(19) United States
(12) Patent Application Publication
(10) Pub. No.: US 2024/0178203 A1
(43) Pub. Date: May 30, 2024

(54) PACKAGING STRUCTURE AND PACKAGING METHOD

(71) Applicant: Semiconductor Manufacturing International (Shanghai) Corporation, Shanghai (CN)

(72) Inventor: Jisong JIN, Shanghai (CN)

(73) Assignee: Semiconductor Manufacturing International (Shanghai) Corporation, Shanghai (CN)

(21) Appl. No.: 18/374,149

(22) Filed: Sep. 28, 2023

(30) Foreign Application Priority Data
Nov. 24, 2022 (CN) 202211482299.X

(51) Int. Cl. H01L 25/10; H01L 21/56; H01L 23/00; H01L 23/31; H01L 23/48; H01L 23/498; H01L 23/538; H01L 25/00

(52) U.S. Cl. CPC H01L 25/105; H01L 21/568; H01L 23/3121; H01L 23/481; H01L 23/49816; H01L 23/5385; H01L 24/16; H01L 24/81; H01L 25/50; H01L 2224/16225; H01L 2224/81801

(57) ABSTRACT

A packaging structure and a packaging method are provided. The packaging method includes: providing a carrier; providing a plurality of device chips, a device chip including a first side and a second side facing away from each other, and an interconnection structure being formed on the first side; attaching the plurality of device chips to the carrier, the second side of the device chip facing the carrier, forming a first packaging layer covering a side wall of the device chip and filling between the device chips on the carrier, the first packaging layer exposing the first side of the device chip; forming a first redistribution structure on the first packaging layer and the device chip; bonding an interconnect chip to the first redistribution structure; and forming a second packaging layer covering the interconnect chip on the first redistribution structure.

### CROSS REFERENCE TO RELATED APPLICATIONS

This application is based on and claims priority to Chinese patent Application No. 202211482299.X, filed Nov. 24, 2022, the entire content of which is incorporated herein by reference.

### TECHNICAL FIELD

The disclosure relates to the technical field of semiconductor packaging, and in particular to a packaging structure and a packaging method.

### BACKGROUND

For monolithic chip sizes, conventional chip manufacturing technologies are being pushed to their limits. However, applications are hungry for the ability to use the latest technology to achieve large size integrated circuits, and it is a great challenge to realize high-speed and small-volume interconnection between chips.

One current solution is to use smaller integrated circuits with Si bridge chips embedded in the silicon substrate to realize the interconnection between chips through the Si bridge chip, thereby providing heterogeneous chip packaging.

However, the interconnection performance between chips still needs to be improved.

### SUMMARY

The disclosure relates to a packaging structure and a packaging method to improve the interconnection performance between device chips.

In an aspect of the disclosure, a packaging structure is provided. The packing structure may include:
a plurality of device chips, a device chip including a first side and a second side facing away from each other, and an interconnection structure being formed on the first side; a first packaging layer, covering a side wall of the device chip and filling between the device chips, the first packaging layer exposing the first side of the device chip; a first redistribution structure, located on the first packaging layer and the device chip, the first redistribution structure being electrically connected to the interconnection structure of the device chip; an interconnect chip, bonded to the first redistribution structure, the interconnect chip being electrically connected to the first redistribution structure; and a second packaging layer, located on the first redistribution structure and covering the interconnect chip.

In an implementation, the first side is a front side of the chip, and the second side is a back side of the chip.

In an implementation, the packaging structure further includes: micro bumps (μbumps), located between the interconnect chip and the first redistribution structure.

In an implementation, the packaging structure further includes: a via interconnection structure, running through the second packaging layer and electrically connected to the first redistribution structure.

In an implementation, the packaging structure further includes: μbumps, located between the interconnect chip and the first redistribution structure, the μbumps being further located on the first redistribution structure exposed by the interconnect chip, and the via interconnection structure running through the first packaging layer on tops of the μbumps exposed by the interconnect chip and contacting the μbumps.

In an implementation, the packaging structure further includes: a second redistribution structure, located on the second packaging layer and the via interconnection structure; and a conductive bump, located on the second redistribution structure.

In an implementation, the first redistribution structure includes one or more redistribution layers.

In another aspect of the disclosure, a packaging method is provided. The method may include:
providing a carrier; providing a plurality of device chips, a device chip including a first side and a second side facing away from each other, and an interconnection structure being formed on the first side; attaching the plurality of device chips to the carrier, the second side of the device chip facing the carrier; forming a first packaging layer covering a side wall of the device chip and filling between the device chips on the carrier, the first packaging layer exposing the first side of the device chip; forming a first redistribution structure on the first packaging layer and the device chip, the first redistribution structure being electrically connected to the interconnection structure of the device chip; bonding an interconnect chip to the first redistribution structure, the interconnect chip being electrically connected to the first redistribution structure; and forming a second packaging layer covering the interconnect chip on the first redistribution structure.

In an implementation, the first side is a front side of the chip, and the second side is a back side of the chip.

In an implementation, in the step of bonding the interconnect chip to the first redistribution structure, the interconnect chip is bonded to the first redistribution structure through μbumps.

In an implementation, the packaging method further includes: after forming the first redistribution structure and before bonding the interconnect chip to the first redistribution structure, forming first μbumps on the first redistribution structure; and in the step of bonding the interconnect chip to the first redistribution structure, bonding the interconnect chip to the first μbumps; alternatively, forming second μbumps on the interconnect chip; and in the step of bonding the interconnect chip to the first redistribution structure, bonding the interconnect chip to the first redistribution structure through the second μbumps; and alternatively, forming the first μbumps on the first redistribution structure, and forming the second μbumps on the interconnect chip; and in the step of bonding the interconnect chip to the first redistribution structure, bonding the first μbumps to the second μbumps.

In an implementation, after forming the second packaging layer, the packaging method further includes: forming a via interconnection structure running through the second packaging layer and electrically connected to the first redistribution structure.

In an implementation, in the step of bonding the interconnect chip to the first redistribution structure, the interconnect chip is bonded to the first redistribution structure through the μbumps, and the μbumps are further formed on the first redistribution structure exposed by the interconnect chip; and in the step of forming the via interconnection structure, the via interconnection structure runs through the second packaging layer on tops of the μbumps exposed by the interconnect chip and contacts the μbumps.

In an implementation, after forming the via interconnection structure, the packaging method further includes: forming a second redistribution structure on the second packaging layer and the via interconnection structure; and forming a conductive bump on the second redistribution structure.

In an implementation, the packaging method further includes: removing, after forming the second packaging layer, the carrier.

Compared with the prior art, the disclosure have the following advantages.

In the packaging structure provided by the example of the disclosure, the first redistribution structure is located on the first packaging layer and the device chip, and the first redistribution structure is electrically connected to the interconnection structure of the device chip; and the interconnect chip is bonded to the first redistribution structure, and the interconnect chip is electrically connected to the first redistribution structure, so that the device chips are electrically connected through the interconnect chip and the first redistribution structure, which is beneficial to improve the interconnection performance between the device chips.

In the packaging method provided by the form of the disclosure, the plurality of device chips are attached to the carrier, and the second side of the device chip faces the carrier; the first packaging layer covering the side wall of the device chip and filling between the device chips is formed on the carrier, and the first packaging layer exposes the first side of the device chip; the first redistribution structure is formed on the first packaging layer and the device chip, and the first redistribution structure is electrically connected to the interconnection structure of the device chip; and the interconnect chip is bonded to the first redistribution structure, and the interconnect chip is electrically connected to the first redistribution structure, so that the device chips are electrically connected through the interconnect chip and the first redistribution structure, which is beneficial to improve the interconnection performance between the device chips. In addition, in the form of the disclosure, the attaching the device chip, forming the first packaging layer, forming the first redistribution structure, bonding the interconnect chip and forming the second packaging layer are all performed on the carrier, so that the process steps of the form of the disclosure are simple. Moreover, only one carrier is needed, which is beneficial to save the process cost.

### BRIEF DESCRIPTION OF THE DRAWINGS

FIG. 1 is a schematic structural diagram of a packaging structure according to a form of the disclosure; and

FIG. 2 to FIG. 12 are schematic structural diagrams corresponding to steps of a packaging method according to a form of the disclosure.

### DETAILED DESCRIPTION

The disclosure provides a packaging structure, including: a plurality of device chips, the device chip including a first side and a second side facing away from each other, and an interconnection structure being formed on the first side; a first packaging layer, covering a side wall of the device chip and filling between the device chips, the first packaging layer exposing the first side of the device chip; a first redistribution structure, located on the first packaging layer and the device chip, the first redistribution structure being electrically connected to the interconnection structure of the device chip; an interconnect chip, bonded to the first redistribution structure, the interconnect chip being electrically connected to the first redistribution structure; and a second packaging layer, located on the first redistribution structure and covering the interconnect chip.

In the packaging structure provided by the form of the disclosure, the first redistribution structure is located on the first packaging layer and the device chip, and the first redistribution structure is electrically connected to the interconnection structure of the device chip; and the interconnect chip is bonded to the first redistribution structure, and the interconnect chip is electrically connected to the first redistribution structure, so that the device chips are electrically connected through the interconnect chip and the first redistribution structure, which is beneficial to improve the interconnection performance between the device chips.

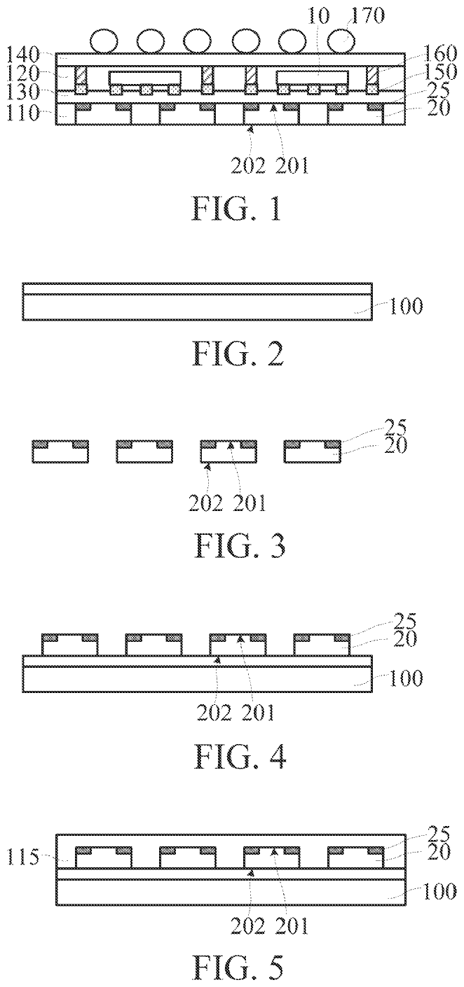

To make the foregoing objectives, features, and advantages of the disclosure more apparent and easier to understand, exemplary forms of the disclosure are described in detail below with reference to the accompanying drawings. FIG. 1 shows a schematic structural diagram of a packaging structure according to a form of the disclosure.

As shown in FIG. 1, in this form, the packaging structure includes: a plurality of device chips 20, the device chip 20 including a first side 201 and a second side 202 facing away from each other, and an interconnection structure 25 being formed on the first side 201; a first packaging layer 110, covering a side wall of the device chip 20 and filling between the device chips 20, the first packaging layer 110 exposing the first side 201 of the device chip 20; a first redistribution structure 130, located on the first packaging layer 110 and the device chip 20, the first redistribution structure 130 being electrically connected to the interconnection structure 25 of the device chip 20; an interconnect chip 10, bonded to the first redistribution structure 130, the interconnect chip 10 being electrically connected to the first redistribution structure 130; and a second packaging layer 120, located on the first redistribution structure 130 and covering the interconnect chip 10.

The plurality of device chips 20 are configured to be packaged together and realize electrical connection with each other, thereby forming the corresponding packaging structure and further realizing specific functions.

In a specific implementation, types of the plurality of device chips 20 may be the same or different. When the types of the device chips 20 are different, heterogeneous integration can be achieved.

In an example, the plurality of device chips 20 include a first device chip (not shown) and a second device chip (not shown). The types of the first device chip and the second device chip are different to realize different functions.

In an example, the first device chip is a high bandwidth memory (HBM) chip. The use of the HBM chip is beneficial to meet the requirements of higher information transmission speed.

In an example, the second device chip is a logic chip for logic control of the first device chip. Specifically, the second device chip may be a CPU chip, a GPU chip or an SoC chip.

In this form, the device chip 20 includes a first side 201 and a second side 202 facing away from each other.

In this form, the first side 201 is a front side of the device chip 20, and the second side 202 is a back side of the device chip 20. In this form, the first side 201 is a side of the device chip 20 for bonding.

In this form, the front side of the chip is a side facing the device in the chip, and the back side of the chip is a side facing away from the device in the chip.

The interconnection structure 25 is used as an external electrode of the device chip 20 to realize electrical connection between the device chip 20 and an external circuit or other interconnection structures. In an example, the interconnection structure 25 is configured to realize electrical connection between the device chip 20 and the first redistribution structure 130.

The interconnection structure 25 is exposed from the first side 201 of the device chip 20 so as to realize electrical connection with an external circuit or other interconnection structures.

In an example, a material of the interconnection structure 25 is a conductive material. More specifically, the material of the interconnection structure 25 is a metal, including any one or more of copper, titanium, aluminum, gold, nickel, iron, tin, silver, zinc or chromium, which is beneficial to obtain good electrical conductivity.

The first packaging layer 110 is configured to realize packaging and integration between the plurality of device chips 20. The first packaging layer 110 can also play roles of insulation, sealing and moisture prevention, which is beneficial to improve the reliability of the packaging structure.

The first packaging layer 110 exposes the first side 201 of the device chip 20, so as to realize electrical connection between the device chip 20 and an external circuit or other interconnection structures.

In an example, a material of the first packaging layer 110 is a molding material, for example, epoxy resin. The epoxy resin has the advantages of low shrinkage, good binding property, good corrosion resistance, excellent electrical properties, low cost, etc. In other forms, the first packaging layer may be made of other appropriate packaging materials.

The first redistribution structure 130 is configured to realize electrical connection between the device chip 20 and the interconnect chip 10, and the first redistribution structure 130 is also configured to realize electrical connection between the device chip 20 and other interconnection structures.

In addition, by arranging the first redistribution structure 130, interconnect terminals of the device chips 20 can also be redistributed, so that other interconnection structures can be arranged on the first redistribution structure 130 or the device chip 20 can be bonded to the first redistribution structure.

In this form, by arranging the first redistribution structure 130 on the first side 201 of the device chip 20, the first redistribution structures 130 with smaller pitch can be obtained, thereby improving the density of the first redistribution structures 130, and accordingly being beneficial to improve the interconnection density and interconnection performance between the device chip 20 and the interconnect chip 10 and accordingly improve the interconnection performance between the device chips 20.

Specifically, the first redistribution structure 130 is arranged on the first side 201 of the device chip 20, and the first packaging layer 110 has high height consistency with the first side 201 of the device chip 20 and high flatness of the top surface, which facilitates the patterning process of forming the first redistribution structure 130 and further facilitates the first redistribution structures 130 with smaller pitch and high density, thereby improving the interconnection density and interconnection performance between the device chip 20 and the interconnect chip 10 and accordingly improving the interconnection performance between the device chips 20.

In addition, in this form, the first redistribution structure 130 can further provide a process platform and a formation basis for the formation of the micro bumps (μbumps) 150. The first redistribution structures 130 have high density and small pitch, so that the μbumps 150 with higher density can be obtained easily, thereby further improving the communication speed between the device chip 20 and the interconnect chip 10.

Specifically, the first redistribution structure 130 may include one or more redistribution layers.

Specifically, a material of the first redistribution structure 130 is a conductive material. More specifically, the material of the first redistribution structure 130 is a metal, including any one or more of copper, titanium, aluminum, gold, nickel, iron, tin, silver, zinc or chromium, which is beneficial to obtain good electrical conductivity.

The interconnect chip 10 is used as a bridge to realize interconnection between the device chip 20 and the device chip 20. In this form, the plurality of device chips 20 include different types of device chips 20, so that the interconnect chip 10 can provide heterogeneous device chip packaging.

In the packaging structure provided by this form, the first redistribution structure 130 is located on the first packaging layer 110 and the device chip 20, and the first redistribution structure 130 is electrically connected to the interconnection structure 25 of the device chip 20; and the interconnect chip 10 is bonded to the first redistribution structure 130, and the interconnect chip 10 is electrically connected to the first redistribution structure 130, so that the device chips 20 are electrically connected through the interconnect chip 10 and the first redistribution structure 130, which is beneficial to improve the interconnection performance between the device chips 20.

Specifically, one or more layers of lines are formed in the interconnect chip 10.

In an example, a pad (not shown) is formed on the interconnect chip 10, and the pad exposes a surface of the interconnect chip 10.

The pad is configured to electrically lead out the interconnect chip 10 to realize electrical connection between the interconnect chip 10 and an external circuit or other interconnection structures.

In an example, the pad is a solder pad. In an example, a material of the pad is a metal, including any one or more of copper, titanium, aluminum, gold, nickel, iron, tin, silver, zinc or chromium.

In this form, the packaging structure further includes: μbumps 150, located between the interconnect chip 10 and the first redistribution structure 130. The μbumps 150 are configured to realize electrical connection between the interconnect chip 10 and the first redistribution structure 130, and also configured to realize interconnection density between the device chip 20 and the interconnect chip 10.

More specifically, in this form, the μbumps 150 are configured to realize electrical connection between the first redistribution structure 130 and the pad.

In this form, the μbumps 150 are further located on the first redistribution structure 130 exposed by the interconnect chip 10, so as to realize electrical connection between the first redistribution structure 130 and other interconnection structures.

In this form, a material of the μbumps 150 includes one or more of tin, copper, aluminum, tungsten, cobalt, nickel, titanium, tantalum, titanium nitride and tantalum nitride. In an example, the material of the μbumps 150 is tin.

The second packaging layer 120 is configured to realize packaging and integration between the interconnect chip 10 and the first redistribution structure 130, and can also play roles of insulation, sealing and moisture prevention, which is beneficial to improve the reliability of the packaging structure.

In an example, a material of the second packaging layer 120 is a molding material, for example, epoxy resin. The epoxy resin has the advantages of low shrinkage, good binding property, good corrosion resistance, excellent electrical properties, low cost, etc. In other forms, the second packaging layer may be made of other appropriate packaging materials.

In this form, the packaging structure further includes: a via interconnection structure 160, running through the second packaging layer 120 and electrically connected to the first redistribution structure 130.

The via interconnection structure 160 is configured to realize electrical connection between the device chip 20 and an external circuit or other interconnection structures.

Specifically, in this form, the via interconnection structure 160 runs through the first packaging layer 110 on tops of the μbumps 150 exposed by the interconnect chip 10 and contacts the μbumps 150.

In this form, the via interconnection structure 160 is a through molding via (TMV).

In this form, a material of the via interconnection structure 160 is a conductive material. More specifically, the material of the via interconnection structure 160 is a metal, including any one or more of copper, titanium, aluminum, gold, nickel, iron, tin, silver, zinc or chromium, which is beneficial to obtain good electrical conductivity.

In this form, the packaging structure further includes: a second redistribution structure 140, located on the second packaging layer 120 and the via interconnection structure 160; and a conductive bump 170, located on the second redistribution structure 140.

In this form, the second redistribution structure 140 is configured to realize electrical connection between the via interconnection structure 160 and an external circuit or other interconnection structures, thereby realizing electrical connection between the device chip 20 and the external circuit through the via interconnection structure 160. In this form, the second redistribution structure 140 is also configured to provide a process platform for the formation of the conductive bump 170.

Specifically, the second redistribution structure 140 may include one or more redistribution layers.

Specifically, a material of the second redistribution structure 140 is a conductive material. More specifically, the material of the second redistribution structure 140 is a metal, including any one or more of copper, titanium, aluminum, gold, nickel, iron, tin, silver, zinc or chromium.

The conductive bump 170 is configured to realize electrical connection between the second redistribution structure 140 and an external circuit (e.g., a substrate).

In this form, the conductive bump 170 is a solder ball. In an example, a material of the solder ball includes tin.

Specifically, the solder ball is C4 (Controlled Collapse Chip Connection), and has excellent electrical properties and thermal characteristics. Moreover, in a case of the same pitch between the solder balls, the I/O number can be very high, and not limited by the size of the second redistribution structure 140. Besides, the solder ball is suitable for mass production, and the size and weight can be greatly reduced.

Accordingly, the disclosure further provides a packaging method. FIG. 2 to FIG. 12 are schematic structural diagrams corresponding to steps of a packaging method according to an form of the disclosure.

The packaging method provided by this form will be described in detail below with reference to the accompanying drawings. Referring to FIG. 2, a carrier 100 is provided.

The carrier 100 is configured to provide a process operation platform for subsequent packaging steps. The carrier 100 is also configured to provide carrying and supporting functions for subsequent process steps.

In this form, the carrier 100 is a carrier wafer. In other forms, the carrier may also be other types of bases. In this form, a material of the carrier may include one or more of silicon, glass, silicon oxide and aluminum oxide.

Referring to FIG. 3, a plurality of device chips 20 are provided. The device chip 20 includes a first side 201 and a second side 202 facing away from each other, and an interconnection structure 25 is formed on the first side 201.

The plurality of device chips 20 are configured to be packaged together subsequently and realize electrical connection with each other, thereby realizing specific functions.

In a specific implementation, types of the plurality of device chips 20 may be the same or different. When the types of the device chips 20 are different, heterogeneous integration can be achieved.

In an example, the plurality of device chips 20 include a first device chip (not shown) and a second device chip (not shown). The types of the first device chip and the second device chip are different to realize different functions.

In an example, the first device chip is a high bandwidth memory (HBM) chip. The use of the HBM chip is beneficial to meet the requirements of higher information transmission speed.

In an example, the second device chip is a logic chip for logic control of the first device chip. Specifically, the second device chip may be a CPU chip, a GPU chip or an SoC chip.

In this form, the device chip 20 includes a first side 201 and a second side 202 facing away from each other.

In this form, the first side 201 is a front side of the device chip 20, and the second side 202 is a back side of the device chip 20.

In this form, the first side 201 is a side of the device chip 20 for bonding.

In this form, the front side of the chip is a side facing the device in the chip, and the back side of the chip is a side facing away from the device in the chip.

The interconnection structure 25 is used as an external electrode of the device chip 20 to realize electrical connection between the device chip 20 and an external circuit or other interconnection structures. The interconnection structure 25 is exposed from the first side 201 of the device chip 20 so as to realize electrical connection with an external circuit or other interconnection structures.

In an example, a material of the interconnection structure 25 is a conductive material. More specifically, the material of the interconnection structure 25 is a metal, including any one or more of copper, titanium, aluminum, gold, nickel, iron, tin, silver, zinc or chromium, which is beneficial to obtain good electrical conductivity.

Referring to FIG. 4, the plurality of device chips 20 are attached to the carrier 100. The second side 202 of the device chip 20 faces the carrier 100.

The plurality of device chips 20 are attached to the carrier 100, thereby facilitating subsequent packaging and integration between the plurality of device chips 20 and subsequent electrical connection between the device chips 20 through the interconnect chip.

The second side 202 of the device chip 20 faces the carrier 100, so that the first side 201 of the device chip 20 faces away from the carrier 100, that is, the first side 201 of the device chip 20 is exposed, thereby facilitating subsequent electrical connection between the device chip 20 and an external circuit or other interconnection structures.

In a specific form, the second side 202 of the device chip 20 can be attached to the carrier 100 by temporary bonding, so as to reduce the difficulty in subsequent removal of the carrier 100.

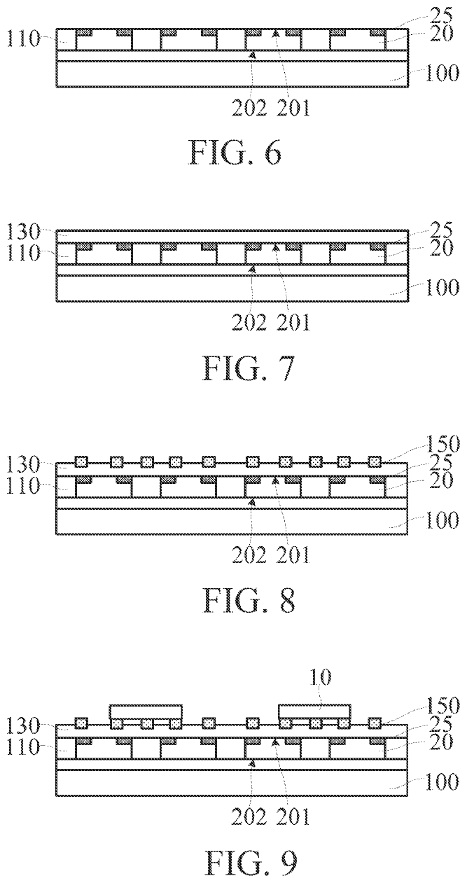

Referring to FIG. 5 to FIG. 6, a first packaging layer 110 covering a side wall of the device chip 20 and filling between the device chips 20 is formed on the carrier 100. The first packaging layer 110 exposes the first side 201 of the device chip 20.

The first packaging layer 110 is configured to realize packaging and integration between the plurality of device chips 20. The first packaging layer 110 can also play roles of insulation, sealing and moisture prevention, which is beneficial to improve the reliability of the packaging structure.

The first packaging layer 110 exposes the first side 201 of the device chip 20, so as to realize electrical connection between the device chip 20 and an external circuit or other interconnection structures.

In an example, a material of the first packaging layer 110 is a molding material, for example, epoxy resin. The epoxy resin has the advantages of low shrinkage, good binding property, good corrosion resistance, excellent electrical properties, low cost, etc. In other forms, the first packaging layer may be made of other appropriate packaging materials.

In an example, the step of forming the first packaging layer 110 includes: as shown in FIG. 5, a first packaging material layer 115 covering a top and the side wall of the device chip 20 is formed on the carrier 100; and the first packaging material layer 115 higher than the first side 201 of the device chip 20 is removed, and the remaining first packaging material layer 115 covering the side wall of the device chip 20 is used as the first packaging layer 110.

In an example, the first packaging material layer 115 may be formed by a molding process. In other forms, the first packaging material layer may also be formed by other appropriate processes based on actual process demands.

In an example, the first packaging material layer 115 higher than the first side 201 of the device chip 20 is removed by a grinding process to improve the flatness of the top surface of the first packaging material layer 115, thereby facilitating subsequent process.

Referring to FIG. 7, a first redistribution structure 130 is formed on the first packaging layer 110 and the device chip 20. The first redistribution structure 130 is electrically connected to the interconnection structure 25 of the device chip 20.

The first redistribution structure 130 is configured to realize electrical connection between the device chip 20 and the subsequent interconnect chip, and the first redistribution structure 130 is also configured to realize electrical connection between the device chip 20 and other interconnection structures.

In addition, by arranging the first redistribution structure 130, interconnect terminals of the device chips 20 can also be redistributed, so that other interconnection structures can be arranged on the first redistribution structure 130 or the device chip 20 can be bonded to the first redistribution structure subsequently.

In this form, by arranging the first redistribution structure 130 on the first side 201 of the device chip 20, the first redistribution structures 130 with smaller pitch can be obtained, thereby improving the density of the first redistribution structures 130, and accordingly being beneficial to improve the interconnection density and interconnection performance between the device chip 20 and the interconnect chip and accordingly improve the interconnection performance between the device chips 20.

Specifically, the first redistribution structure 130 is arranged on the first side 201 of the device chip 20, and the first packaging layer 110 has high height consistency with the first side 201 of the device chip 20 and high flatness of the top surface, which facilitates the patterning process of forming the first redistribution structure 130 and further facilitates the first redistribution structures 130 with smaller pitch and high density, thereby improving the interconnection density and interconnection performance between the device chip 20 and the interconnect chip and accordingly improving the interconnection performance between the device chips 20.

In addition, in this form, the first redistribution structure 130 can further provide a process platform and a formation basis for the formation of the μbumps. The first redistribution structures 130 have high density and small pitch, so that the μbumps with higher density can be obtained easily, thereby further improving the communication speed between the device chip 20 and the interconnect chip.

Specifically, the first redistribution structure 130 may include one or more redistribution layers.

Specifically, a material of the first redistribution structure 130 is a conductive material. More specifically, the material of the first redistribution structure 130 is a metal, including any one or more of copper, titanium, aluminum, gold, nickel, iron, tin, silver, zinc or chromium, which is beneficial to obtain good electrical conductivity.

Referring to FIG. 8 to FIG. 9, an interconnect chip 10 is bonded to the first redistribution structure 130. The interconnect chip 10 is electrically connected to the first redistribution structure 130.

The interconnect chip 10 is used as a bridge to realize interconnection between the device chip 20 and the device chip 20. In this form, the plurality of device chips 20 include different types of device chips 20, so that the interconnect chip 10 can provide heterogeneous chip packaging.

In the packaging structure provided by this form, the first redistribution structure 130 is located on the first packaging layer 110 and the device chip 20, and the first redistribution structure 130 is electrically connected to the interconnection structure 25 of the device chip 20; and the interconnect chip 10 is bonded to the first redistribution structure 130, and the interconnect chip 10 is electrically connected to the first redistribution structure 130, so that the device chips 10 are electrically connected through the interconnect chip 10 and the first redistribution structure 130, which is beneficial to improve the interconnection performance between the interconnect chips 10.

Specifically, one or more layers of lines are formed in the interconnect chip 10.

In an example, a pad (not shown) is formed on the interconnect chip 10, and the pad exposes a surface of the interconnect chip 10.

The pad is configured to electrically lead out the interconnect chip 10 to realize electrical connection between the interconnect chip 10 and an external circuit or other interconnection structures.

In an example, the pad is a solder pad. In an example, a material of the pad is a metal, including any one or more of copper, titanium, aluminum, gold, nickel, iron, tin, silver, zinc or chromium.

It should be noted that in this form, in the step of bonding the interconnect chip 10 to the first redistribution structure 130, the interconnect chip 10 is bonded to the first redistribution structure 130 through μbumps 150.

The μbumps 150 are configured to realize electrical connection between the interconnect chip 20 and the first redistribution structure 130, and also configured to realize interconnection density between the device chip 20 and the interconnect chip 10.

More specifically, in this form, the μbumps 150 are configured to realize electrical connection between the first redistribution structure 130 and the pad.

In this form, the μbumps 150 are further located on the first redistribution structure 130 exposed by the interconnect chip 20, so as to realize electrical connection between the first redistribution structure 130 and other interconnection structures.

In this form, a material of the μbumps 150 includes one or more of tin, copper, aluminum, tungsten, cobalt, nickel, titanium, tantalum, titanium nitride and tantalum nitride. In an example, the material of the μbumps 150 is tin.

More specifically, in this form, the packaging method further includes: after forming the first redistribution structure 130 and before bonding the interconnect chip 10 to the first redistribution structure 130, first μbumps 150 are formed on the first redistribution structure 130; and in the step of bonding the interconnect chip 10 to the first redistribution structure 130, the interconnect chip 10 is bonded to the first μbumps 150.

Alternatively, in other forms, after forming the first redistribution structure and before bonding the interconnect chip to the first redistribution structure, second μbumps are formed on the interconnect chip; and in the step of bonding the interconnect chip to the first redistribution structure, the interconnect chip is bonded to the first redistribution structure through the second μbumps.

Alternatively, in some other forms, after forming the first redistribution structure and before bonding the interconnect chip to the first redistribution structure, the first μbumps are formed on the first redistribution structure, and the second μbumps are formed on the interconnect chip; and in the step of bonding the interconnect chip to the first redistribution structure, the first μbumps are bonded to the second μbumps.

In this form, in the step of bonding the interconnect chip 10 to the first redistribution structure 130, the interconnect chip 10 is bonded to the first redistribution structure 130 through the μbumps 150, and the μbumps 150 are further formed on the first redistribution structure 130 exposed by the interconnect chip 10.

The μbumps 150 are further formed on the first redistribution structure 130 exposed by the interconnect chip 10, so that the device chip 20 can be electrically connected to an external circuit or other interconnection structures through the μbumps 150 and the first redistribution structure 130 subsequently.

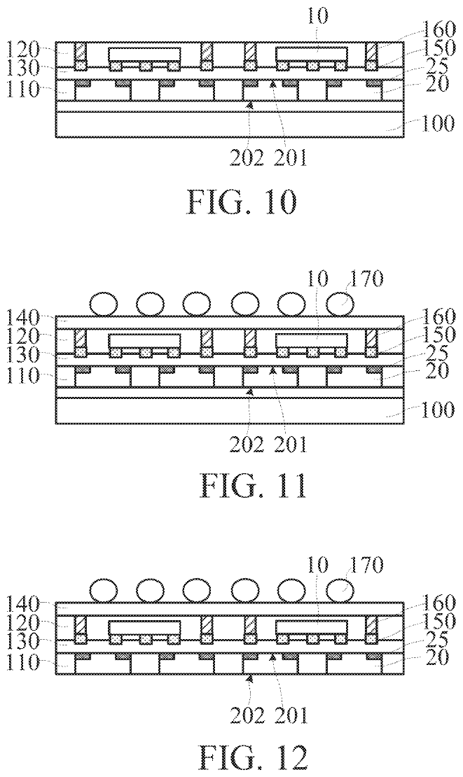

Referring to FIG. 10, a second packaging layer 120 covering the interconnect chip 10 is formed on the first redistribution structure 130.

The second packaging layer 120 is configured to realize packaging and integration between the interconnect chip 10 and the first redistribution structure 130, and can also play roles of insulation, sealing and moisture prevention, which is beneficial to improve the reliability of the packaging structure.

In an example, a material of the second packaging layer 120 is a molding material, for example, epoxy resin. The epoxy resin has the advantages of low shrinkage, good binding property, good corrosion resistance, excellent electrical properties, low cost, etc. In other forms, the second packaging layer may be made of other appropriate packaging materials.

In an example, the second packaging layer 120 is formed by a molding process. In other forms, the second packaging layer may also be formed by other appropriate processes based on actual process demands.

It should be noted that in this form, after forming the second packaging layer 120, the packaging method further includes: forming a via interconnection structure 160 running through the second packaging layer 120 and electrically connected to the first redistribution structure 130.

The via interconnection structure 160 is configured to realize electrical connection between the device chip 20 and an external circuit or other interconnection structures.

Specifically, in this form, the via interconnection structure 160 runs through the first packaging layer 110 on tops of the μbumps 150 exposed by the interconnect chip 10 and contacts the μbumps 150.

In this form, the via interconnection structure 160 is a through molding via (TMV).

In this form, a material of the via interconnection structure 160 is a conductive material. More specifically, the material of the via interconnection structure 160 is a metal, including any one or more of copper, titanium, aluminum, gold, nickel, iron, tin, silver, zinc or chromium, which is beneficial to obtain good electrical conductivity.

Referring to FIG. 11, in a specific implementation, after forming the via interconnection structure 160, the packaging method further includes: forming a second redistribution structure 140 on the second packaging layer 120 and the via interconnection structure 160; and forming a conductive bump 170 on the second redistribution structure 140.

In this form, the second redistribution structure 140 is configured to realize electrical connection between the via interconnection structure 160 and an external circuit or other interconnection structures, thereby realizing electrical connection between the device chip 20 and the external circuit through the via interconnection structure 160. In this form, the second redistribution structure 140 is also configured to provide a process platform for the formation of the conductive bump 170.

Specifically, the second redistribution structure 140 may include one or more redistribution layers.

Specifically, a material of the second redistribution structure 140 is a conductive material. More specifically, the material of the second redistribution structure 140 is a metal, including any one or more of copper, titanium, aluminum, gold, nickel, iron, tin, silver, zinc or chromium.

The conductive bump 170 is configured to realize electrical connection between the second redistribution structure 140 and an external circuit (e.g., a substrate).

In this form, the conductive bump 170 is a solder ball. In an example, a material of the solder ball includes tin.

Specifically, the solder ball is C4 (Controlled Collapse Chip Connection), and has excellent electrical properties and thermal characteristics. Moreover, in a case of the same pitch between the solder balls, the I/O number can be very high, and not limited by the size of the second redistribution structure 140. Besides, the solder ball is suitable for mass production, and the size and weight can be greatly reduced.

Referring to FIG. 12, it should be noted that in this form, after forming the second packaging layer 140, the carrier 100 is removed. The carrier 100 is removed, thereby exposing the surface of the first packaging layer 110 facing away from the interconnect chip 10 and the second side 20 of the device chip 20, and facilitating subsequent electrical connection between the conductive bump 170 and the external circuit (e.g., PCB).

More specifically, in this form, after forming the conductive bump 170, the carrier 100 is removed. In an example, the carrier 100 may be removed by debonding.

In the packaging method provided by this form, the plurality of device chips 20 are attached to the carrier 100, and the second side 202 of the device chip 20 faces the carrier 100; the first packaging layer 110 covering the side wall of the device chip 20 and filling between the device chips 20 is formed on the carrier 100, and the first packaging layer 110 exposes the first side 201 of the device chip 20; the first redistribution structure 130 is formed on the first packaging layer 110 and the device chip 20, and the first redistribution structure 130 is electrically connected to the interconnection structure 25 of the device chip 20; and the interconnect chip 10 is bonded to the first redistribution structure 130, and the interconnect chip 10 is electrically connected to the first redistribution structure 130, so that the device chips 20 are electrically connected through the interconnect chip 10 and the first redistribution structure 130, which is beneficial to improve the interconnection performance between the device chips 20. In addition, in this form, the attaching the device chip 20, forming the first packaging layer 110, forming the first redistribution structure 130, bonding the interconnect chip 10 and forming the second packaging layer 120 are all performed on the carrier 100, so that the process steps of this form are simple. Moreover, only one carrier 100 is needed, which is beneficial to save the process cost.

Although the disclosure has been described above, the disclosure is not limited thereto. Any person skilled in the art can make various changes and modifications without departing from the spirit and scope of the disclosure, so the scope of protection of the disclosure shall be subject to the scope defined by the claims.

What is claimed is:

1. A packaging structure, comprising:
a plurality of device chips, where a device chip of the plurality of device chips comprises a first side and a second side facing away from the first side, and an interconnection structure is formed on the first side of the device chip;
a first packaging layer, covering a side wall of the device chip and filling between device chips of the plurality of device chips, the first packaging layer exposing the first side of the device chip;
a first redistribution structure, located on the first packaging layer and the device chip, the first redistribution structure being electrically connected to the interconnection structure of the device chip;
an interconnect chip, bonded to the first redistribution structure, the interconnect chip being electrically connected to the first redistribution structure; and
a second packaging layer, located on the first redistribution structure and covering the interconnect chip.

2. The packaging structure according to claim 1, wherein the first side is a front side of the device chip, and the second side is a back side of the device chip.

3. The packaging structure according to claim 1, wherein the packaging structure further comprises:
micro bumps, located between the interconnect chip and the first redistribution structure.

4. The packaging structure according to claim 1, wherein the packaging structure further comprises:
a via interconnection structure, running through the second packaging layer and electrically connected to the first redistribution structure.

5. The packaging structure according to claim 4, wherein the packaging structure further comprises:
micro bumps, located between the interconnect chip and the first redistribution structure, the micro bumps being further located on the first redistribution structure exposed by the interconnect chip, and the via interconnection structure running through the first packaging layer on tops of the micro bumps exposed by the interconnect chip and contacting the micro bumps.

6. The packaging structure according to claim 4, wherein the packaging structure further comprises:
a second redistribution structure, located on the second packaging layer and the via interconnection structure; and
a conductive bump, located on the second redistribution structure.

7. The packaging structure according to claim 1, wherein the first redistribution structure comprises one or more redistribution layers.

8. A packaging method, comprising:
providing a carrier;
providing a plurality of device chips, where a device chip comprises a first side and a second side facing away from the first side, the device chip is one of the plurality of device chips, and an interconnection structure is formed on the first side of the device chip;
attaching the plurality of device chips to the carrier, the second side of the device chip facing the carrier;
forming a first packaging layer covering a side wall of the device chip and filling between device chips of the plurality of device chips on the carrier, the first packaging layer exposing the first side of the device chip;
forming a first redistribution structure on the first packaging layer and the device chip, the first redistribution structure being electrically connected to the interconnection structure of the device chip;
bonding an interconnect chip to the first redistribution structure, the interconnect chip being electrically connected to the first redistribution structure; and
forming a second packaging layer covering the interconnect chip on the first redistribution structure.

9. The packaging method according to claim 8, wherein the first side is a front side of the device chip, and the second side is a back side of the device chip.

10. The packaging method according to claim 8, wherein in the step of bonding the interconnect chip to the first redistribution structure, the interconnect chip is bonded to the first redistribution structure through micro bumps.

11. The packaging method according to claim 10, wherein the packaging method further comprises:
forming first micro bumps on the first redistribution structure; and
in the step of bonding the interconnect chip to the first redistribution structure, bonding the interconnect chip to the first micro bumps;

12. The packaging method according to claim 10, wherein the packaging method further comprises:
forming second micro bumps on the interconnect chip; and
in the step of bonding the interconnect chip to the first redistribution structure, bonding the interconnect chip to the first redistribution structure through the second micro bumps; and

13. The packaging method according to claim 10, wherein the packaging method further comprises:
forming a first micro bumps on the first redistribution structure, and forming a second micro bumps on the interconnect chip; and
in the step of bonding the interconnect chip to the first redistribution structure, bonding the first micro bumps to the second micro bumps.

14. The packaging method according to claim 8, wherein after forming the second packaging layer, the packaging method further comprises:
forming a via interconnection structure running through the second packaging layer and electrically connected to the first redistribution structure.

15. The packaging method according to claim 14, wherein in the step of bonding the interconnect chip to the first redistribution structure, the interconnect chip is bonded to the first redistribution structure through micro bumps, and the micro bumps are further formed on the first redistribution structure exposed by the interconnect chip; and
in the step of forming the via interconnection structure, the via interconnection structure runs through the second packaging layer on tops of the micro bumps exposed by the interconnect chip and contacts the micro bumps.

16. The packaging method according to claim 14, wherein after forming the via interconnection structure, the packaging method further comprises:
forming a second redistribution structure on the second packaging layer and the via interconnection structure; and
forming a conductive bump on the second redistribution structure.

17. The packaging method according to claim 8, wherein the packaging method further comprises:
removing, after forming the second packaging layer, the carrier.
